(19) United States
(12) Patent Application Publication
(10) Pub. No.: US 2014/0227876 A1
(43) Pub. Date: Aug. 14, 2014

(54) SEMICONDUCTOR DEVICE MANUFACTURING METHOD

(71) Applicant: TOKYO ELECTRON LIMITED, Tokyo (JP)

(72) Inventor: Kazuhito Tohnoe, Miyagi (JP)

(73) Assignee: TOKYO ELECTRON LIMITED, Tokyo (JP)

(21) Appl. No.: 14/347,487

(22) PCT Filed: Oct. 5, 2012
(86) PCT No.: PCT/JP2012/006417

§ 371 Date: Mar. 26, 2014

(30) Foreign Application Priority Data
Oct. 6, 2011 (JP) 2011-222377

(51) Int. Cl. H01L 21/3065

(52) U.S. Cl. CPC H01L 21/30655
USPC 438/695

(57) ABSTRACT

In a semiconductor device manufacturing method having a plasma etching process, a substrate is plasma etched using a resist layer as a mask. The plasma etching process has: a first etching step wherein a mixed gas having a deposition gas and an etching gas mixed at a ratio is introduced into the processing chamber, and the substrate is plasma etched in the mixed gas atmosphere; and a step of repeating multiple times a deposition step, wherein the deposition gas is introduced into the processing chamber, and the plasma-etched substrate is subjected to deposition treatment in an atmosphere having the deposition gas as a main component, and a second etching step, wherein the etching gas is introduced into the processing chamber, and the substrate that has been subjected to the deposition treatment in the deposition step is plasma etched in an atmosphere having the etching gas as a main component.

### FIELD OF THE INVENTION

The present invention relates to a semiconductor device manufacturing method including a plasma etching process for performing etching using a plasma.

### BACKGROUND OF THE INVENTION

In a semiconductor device manufacturing field, various attempts to increase integrity have been made by miniaturization of semiconductor devices. Recently, the attempt to increase integrity per unit area is being actively made by lamination of semiconductor devices which is referred to as three-dimensional mounting.

The laminated semiconductor devices have an electrode penetrating through a substrate having, e.g., a silicon layer, and are electrically connected to one another via the electrode. In order to form the electrode penetrating through the substrate, a resist is coated on the substrate by a coating device, exposed by an exposure device, and developed by a developing device. As a consequence, a resist pattern made of a resist film is formed. Further, a hole such as a through hole or a via hole is formed by etching the substrate while using the formed resist pattern as a mask by using, e.g., a plasma etching apparatus.

Recently, it is required to form a hole having a depth of about 100 μm or above and perform plasma etching for a long period of time. Further, recent semiconductor device requires further miniaturization, so that it is required to form a hole having a relatively small diameter of about 10 μm to 20 μm. However, along with the trend toward the miniaturization of the semiconductor devices, the thickness of the resist film needs to be reduced in order to ensure shape accuracy. Meanwhile, the etching rate of the silicon layer to the etching rate of the resist film, i.e., the selectivity, is not considerably high. Therefore, if the plasma etching is performed for a long period of time, the mask is removed.

Accordingly, in order to form a hole having a small inner diameter and a large depth, whose aspect ratio, i.e., a ratio of the depth to the inner diameter, is high, a silicon oxide film may be used as the mask, instead of the resist film (see, e.g., Patent Document 1). Since the selectivity of the silicon layer to the silicon oxide film is higher than to the resist film, the mask is not removed even if the plasma etching is performed for a long period of time.
Patent Document 1: Japanese Patent Application Publication No. H11-97414

In a conventional etching process including a step of forming a protective film on a top surface and a sidewall of the resist pattern and a step of performing plasma etching on the silicon layer, the protective film needs to have a thickness that is enough to endure exposure to the plasma for a long period of time. This leads to increase in a period of time for the step of forming the protective film, so that a period of time for the entire plasma etching is increased. Therefore, the silicon layer cannot be etched at a high speed, and the productivity of the semiconductor devices deteriorates.

Further, as the diameter of the formed hole is decreased, a ratio of the thickness of the protective film formed on the sidewall of the hole to the diameter of the hole is increased. A difference in the thickness of the protective film in the depth direction of the hole or the like makes it difficult to form a vertical sidewall shape. Further, as the diameter of the formed hole is decreased, the etching gas for depositing the protective film is difficult reach the sidewall of the hole and it is difficult to form the protective film. As a result, the generation of undercut cannot be suppressed, and it is difficult to form the sidewall of the hole to be perpendicular to the surface of the substrate.

### SUMMARY OF THE INVENTION

In view of the above, the present invention provides a semiconductor device manufacturing method including a plasma etching process in which a silicon layer can be etched at a high speed and a sidewall of a hole can be formed to be perpendicular to a surface of a substrate in the case of forming the hole by etching the surface of the substrate where a resist pattern is formed.

A semiconductor device manufacturing method including: a step of holding a substrate to be processed in a processing chamber, the substrate having a resist layer formed in a predetermined pattern on a main surface of a silicon layer; a first etching step in which a mixed gas having a deposition gas and an etching gas mixed at a predetermined ratio is introduced into a processing chamber and the substrate is plasma etched in the mixed gas atmosphere by using the resist layer as a mask; and a repetition step of repeating a plurality of times a deposition step in which the deposition gas is introduced into the processing chamber and the substrate that has been plasma etched in the first etching step is subjected to deposition treatment in an atmosphere having the deposition gas as a main component and a second etching step in which the etching gas is introduced into the processing chamber and the substrate that has been subjected to the deposition treatment in the deposition step is plasma etched in an atmosphere having the etching gas as a main component.

In accordance with the present invention, it is possible to provide a semiconductor device manufacturing method including a plasma etching process in which a silicon layer can be etched at a high speed and a sidewall of a hole can be formed to be perpendicular to a surface of a substrate.

### BRIEF DESCRIPTION OF THE DRAWINGS

FIG. 1 shows a plasma emission intensity in a dynamic process.

FIG. 2 shows etching rate ratios in a general process and the dynamic process.

FIG. 3 shows examples of gas compositions in processes in an embodiment.

FIG. 4 explains a scallop generation mechanism.

FIG. 5 shows a via shape in the case of forming a via having a high aspect ratio.

FIG. 6 shows via formation by a manufacturing method in accordance with the embodiment.

FIG. 7 shows a configuration of a manufacturing apparatus for implementing the manufacturing method in accordance with the embodiment.

FIG. 8 shows a horizontal cross section of a dipole ring magnet 24.

FIG. 9 shows relationship between an electric field EL and a horizontal magnetic field B.

FIG. 10 shows a configuration of a gas control unit of the manufacturing apparatus in accordance with the embodiment.

FIG. 11 is a flowchart showing processes of the manufacturing method in accordance with the embodiment.

FIGS. 12A to 12D show via formation by the manufacturing method in accordance with the embodiment of the present invention.

FIG. 13 shows a specific example of the via formed by the manufacturing method in accordance with the embodiment.

FIG. 14 shows a comparative example of the via.

FIG. 15 shows shapes of vias formed by the plasma etching.

FIG. 16 shows etching rates in the case of forming the via by the plasma etching.

FIGS. 17A to 17F show another example of via formation by the manufacturing method in accordance with the embodiment.

### DETAILED DESCRIPTION OF THE EMBODIMENTS

(Via Formation by Plasma Etching)

In the case of forming a via having a high aspect ratio by plasma etching, a silicon layer is etched by using, e.g., SF₆ gas. As shown in a reaction formula (1), SiF₄ (tetrafluorosilane) is generated by reaction between fluorine radical and Si.

4F*+Si→SiF₄ (1)

SiF₄ generated in a via is discharged to the outside of the via. However, when an etching rate of silicon reaches about several tens of μm/min, the generation amount of SiF₄ is increased, and the amount of fluorine radicals newly supplied into the via and the amount of reaction products (SiF₄) discharged from the via become substantially the same order. Therefore, a partial pressure of SiF₄ inside the via is increased, and a partial pressure of fluorine radical is decreased, which makes it difficult to increase the etching rate. In other words, as the depth of the formed via is increased, the etching rate reaches a peak.

Meanwhile, in the case of employing an etching condition in which the reaction ratio of fluorine radicals is increased, the etching reaction becomes isotropic and, thus, an abnormal shape referred to as a bowing shape becomes remarkable at the upper portion of the upper opening of the via. In other words, it is difficult to form a via having a high aspect ratio at a high etching rate only by increasing the reaction of fluorine radical. Therefore, in the plasma etching method of the present embodiment, in order to maintain a high etching rate and a good via shape, a dynamic process for performing multiple cycles of two or more steps is employed in addition to a general plasma etching process.

(Dynamic Process)

In a dynamic process, a deposition step and an etching step of a relatively short period of time are repeated multiple times. A plasma transition state may be intentionally set between the steps. In other words, it is preferable to repeat the deposition step and the etching step at least three times without extinguishing a plasma between the steps.

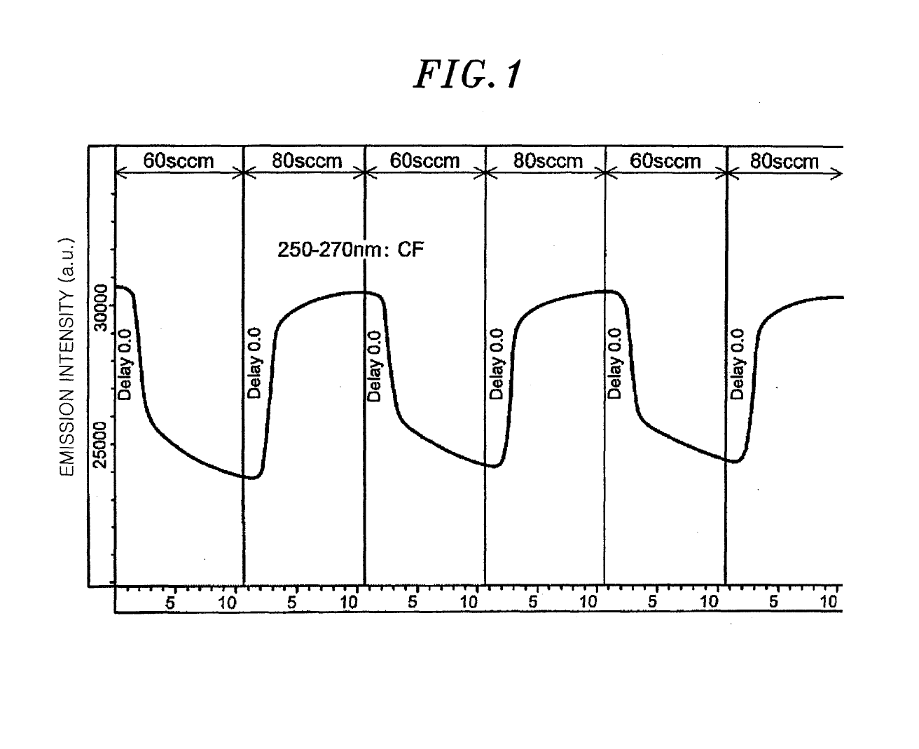

FIG. 1 shows an example of a plasma emission intensity in the dynamic process. In the example shown in FIG. 1, the plasma generation conditions are set as follows.

Pressure: 4.7 Pa (35 mTorr)

High frequency power (H/L): 2000/4000 W

Processing gas (first step (10 sec)): C₄F₆/O₂/Ar=60/65/200 sccm

Processing gas (second step (10 sec)): C₄F₆/O₂/Ar=80/65/200 sccm

Here, the emission intensity of CF at wavelengths of 250 to 270 is shown. In the example of the dynamic process shown in FIG. 1, the first step in which deposition is main and the second step in which etching is main are repeated at the interval of about 10 seconds. As shown in FIG. 1, in the dynamic process, by intentionally deviating the transition point between the first and the second step and the change point of the plasma emission intensity, the plasma generation conditions are controlled such that the plasma emission intensity in the first step is maintained for a while even if the first step is shifted to the second step and the plasma emission intensity in the second step is maintained for a while even if the second step is shifted to the first step. In other words, the plasma transition state is intentionally set. At this time, it is preferable to set the processing time of each of the first and the second step to about 1 to 15 seconds and repeat the first and the second step multiple times. Further, it is preferable that a total flow rate of the processing gas in the first step and a total flow rate of the processing gas in the second step are the same or substantially the same.

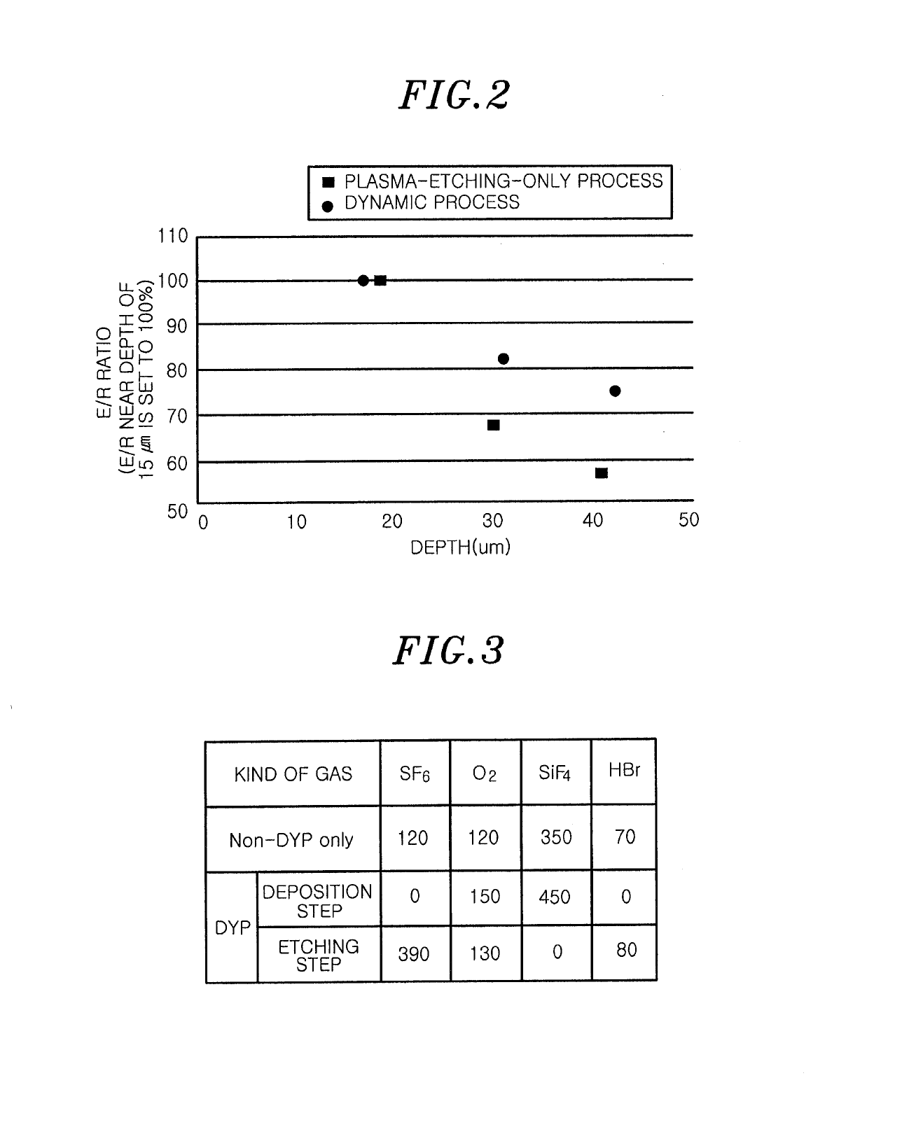

FIG. 2 compares an etching rate ratio (extension ratio) in the case of forming a via only by plasma etching (by etching step only) and an etching rate ratio in the case of forming a via by the dynamic process described in FIG. 1. As shown in FIG. 2, if the depth of the via is increased from 20 μm to 40 μm, the etching rate is decreased to 60% or less in the case of the etching step only. On the other hand, in the dynamic process, it is possible to maintain an etching rate that is improved by about 20% compared to that in the case of the etching step only.

As described above, in the dynamic process, a pattern having a good shape can be formed with a high selectivity while maintaining a good etching rate compared to that in the plasma-etching-only process.

(Limit of Dynamic Process)

FIG. 3 compares an example of kinds of gases used in the plasma-etching-only process (hereinafter, referred to as “Non-DYP”) and an example of kinds of gases used in the dynamic process (hereinafter, referred to as “DYP”). As shown in FIG. 3, in the plasma-etching-only process, deposition gases (SiF₄ and O₂) for forming a SiOx-based protective film by reaction between SiFx radicals and oxygen are mixed with an etching gas (SF₆) for supplying fluorine radicals mentioned in the reaction formula (1). On the other hand, in the dynamic process, a gas having a deposition gas as a main element is supplied in the deposition step and a gas having an etching gas as a main element is supplied in the etching step. Oxygen is supplied in the etching step of the dynamic process in order to protect the entrance of the via.

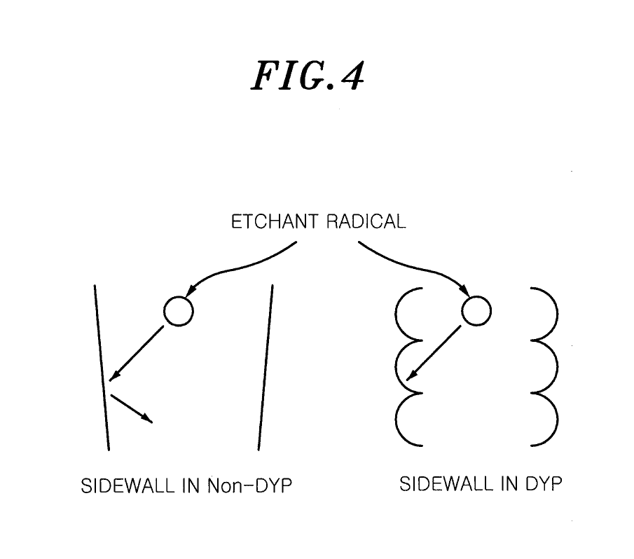

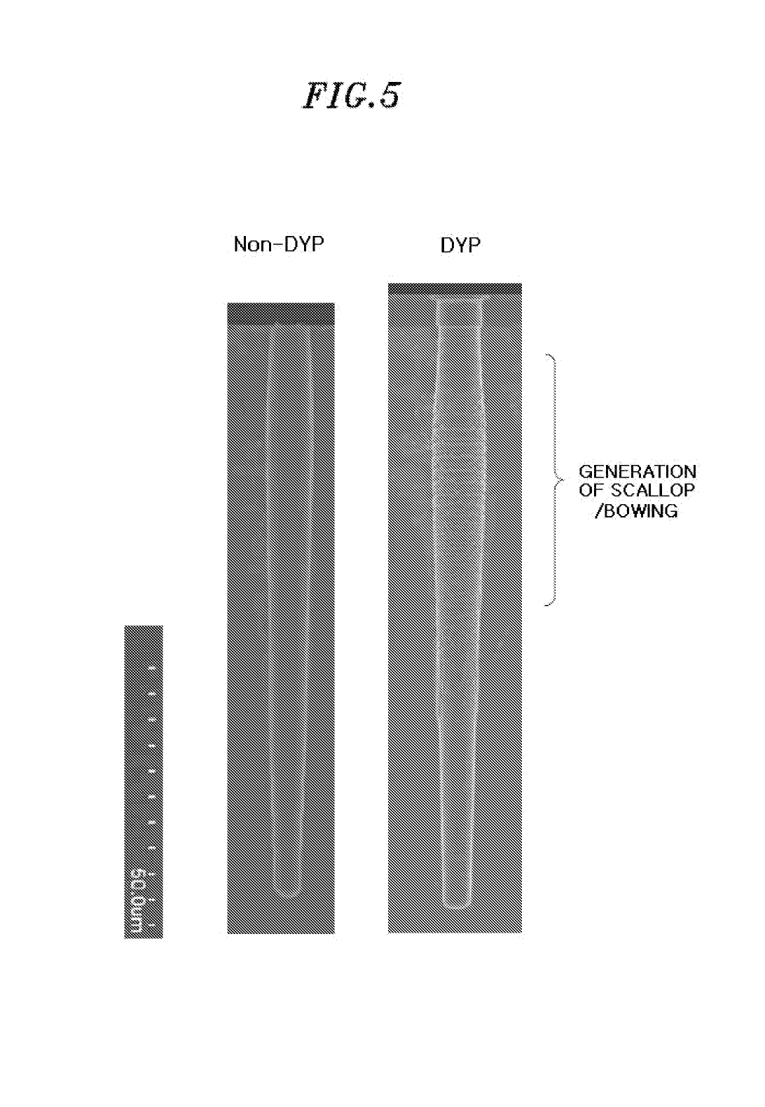

As can be seen from FIG. 4 that compares the plasma-etching-only process and the dynamic process, a stripe recess (scallop) is easily formed on the sidewall of the via in the dynamic process. This is because the deposition step in which a deposition element mainly acts and the etching step in which an etching element stronger than that in the plasma-etching-only process mainly acts are repeated at a relatively short cycle. Here, if etchant radicals moving isotropically enter the via as shown in FIG. 4, in the dynamic process, the etchant radicals are trapped by the scallop formed on the sidewall of the via. In the dynamic process, the possibility in which the scallop grows to result in a bowing shape is higher than that in the plasma-etching-only process. Therefore, in the case of forming a via having a high aspect ratio by the dynamic process, the scallop or the bowing tends to be easily formed as shown in FIG. 5, and this makes the via shape poor.

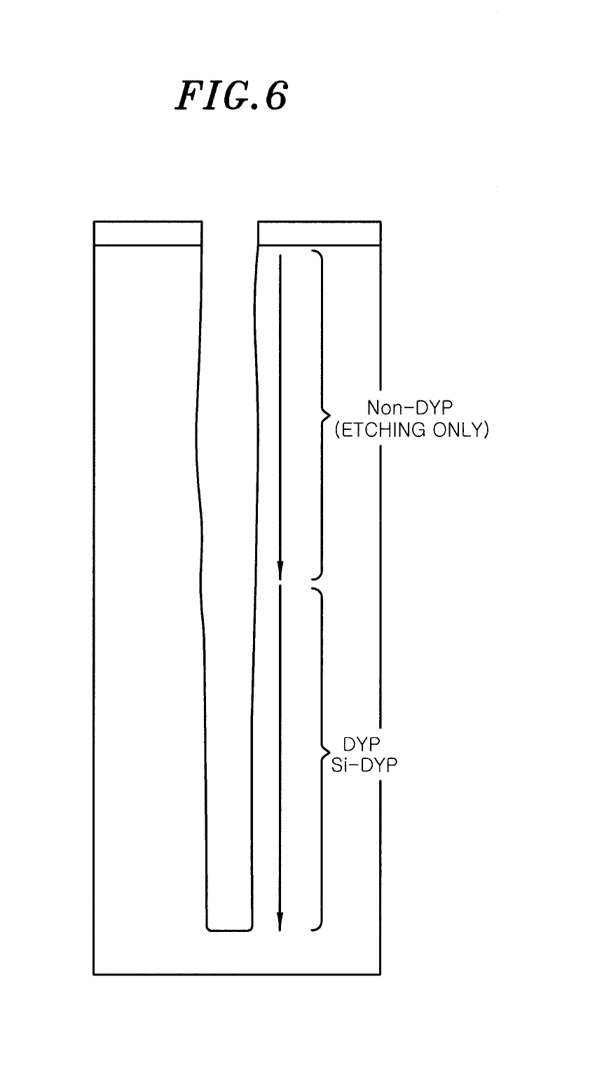

Accordingly, in the plasma etching method of the present embodiment, as shown in FIG. 6, the plasma-etching-only process is performed in the step in which the depth of the via is small and the bowing easily occurs in the dynamic process, and the dynamic process is performed in the step in which the depth of the via is greater. As a consequence, it is expected to obtain the effect of preventing the sidewall of the via from becoming rough by the formation of the deposition film and the effect of improving selectivity by the mask deposition.

(Plasma Etching Apparatus of the Embodiment)

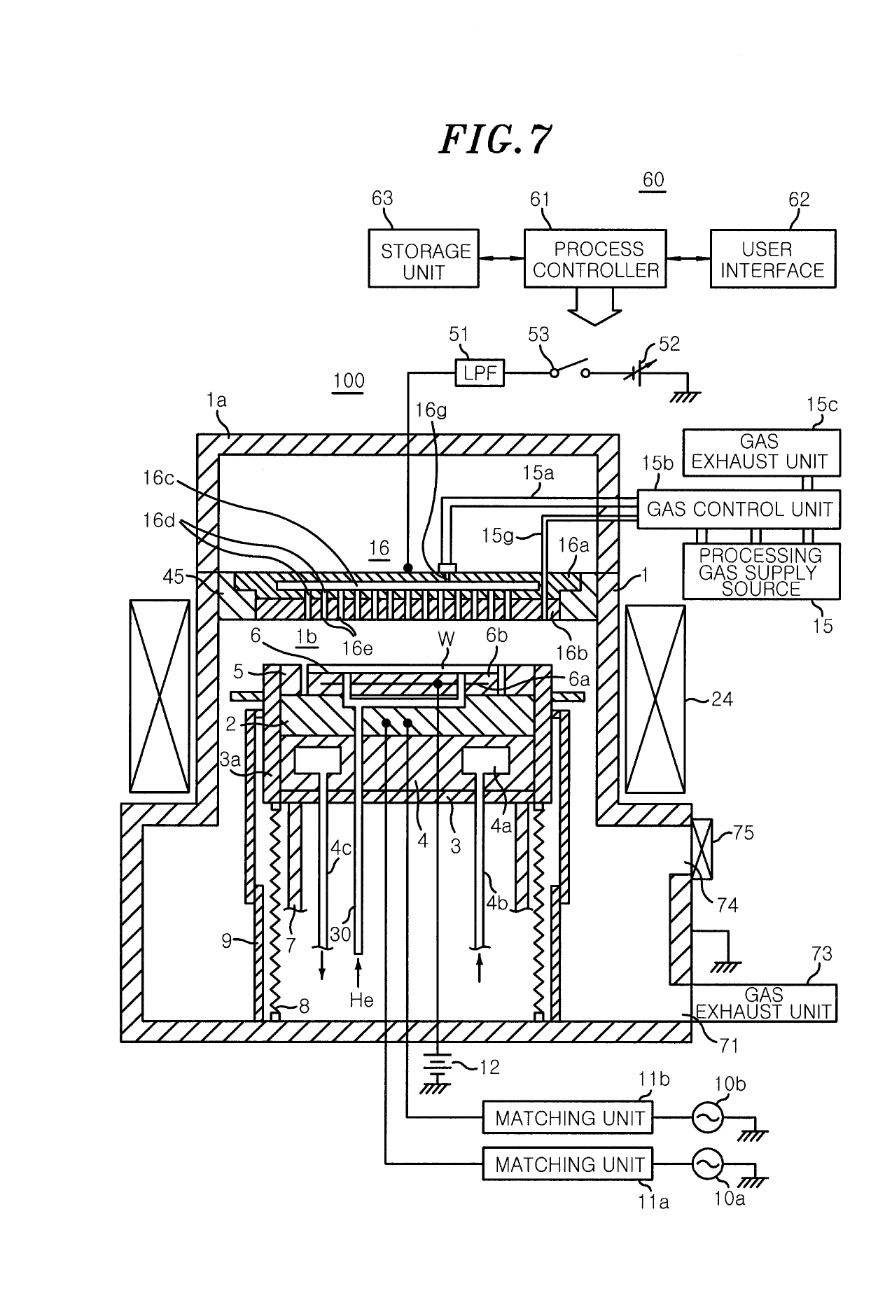

FIG. 7 schematically shows a plasma etching apparatus 100 for implementing the plasma etching method in accordance with the embodiment of the present invention. The plasma etching apparatus 100 includes an airtight processing chamber 1 that is maintained at an electrically ground potential. The processing chamber 1 has a cylindrical shape and is made of, e.g., aluminum having an anodically oxidized surface or the like.

Provided in the processing chamber 1 is a mounting table 2 for horizontally supporting a semiconductor wafer W as a substrate to be processed. The mounting table 2 is made of, e.g., aluminum having an anodically oxidized surface or the like, and serves as a lower electrode. The mounting table 2 is supported by a conductive support 4 and vertically movable by an elevation unit (not shown) having a ball screw 7 through an insulating plate 3. The elevation unit having the ball screw 7 is provided in the processing chamber 1. The elevation unit is covered by a bellows 8 made of stainless steel. A bellows cover 9 is provided at the outer side of the bellows 8. In addition, a focus ring 5 formed of, e.g., single-crystalline silicon, is disposed on the outer periphery of the top surface of the mounting table 2. Besides, a cylindrical inner wall member 3a made of, e.g., quartz or the like, is provided to surround the mounting table 2 and the support 4.

The mounting table 2 is connected to a first high frequency power supply 10a via a first matching unit 11a and also connected to a second high frequency power supply 10b via a second matching unit 11b. The first high frequency power supply 10a is used for plasma generation and supplies a high frequency power having a predetermined frequency (higher than or equal to 27 MHz, e.g., 40 MHz) to the mounting table 2. Further, the second high frequency power supply 10b is used for ion attraction (bias) and supplies a high frequency power having a predetermined frequency (lower than or equal to 13.56 MHz, e.g., 2 MHz) lower than that of the first high frequency power supply 10a to the mounting table 2. Meanwhile, a shower head 16 serving as an upper electrode is provided above the mounting table 2 so as to face the mounting table 2 in parallel. The shower head 16 and the mounting table 2 serve as a pair of electrodes (upper electrode and lower electrode).

An electrostatic chuck 6 for electrostatically attracting and holding the semiconductor wafer W is provided on the top surface of the mounting table 2. The electrostatic chuck 6 has a structure in which an electrode 6a is embedded between an insulator 6b, and the electrode 6a is connected to a DC power supply 12. The semiconductor wafer W is attracted and held by a Coulomb force or the like which is generated by a DC voltage applied from the DC power supply 12 to the electrode 6a.

A coolant path 4a is formed inside the support 4 and connected to a coolant inlet line 4b and a coolant outlet line 4c. By circulating a proper coolant, e.g., cooling water or the like, through the coolant path 4a, the temperatures of the support 4 and the mounting table 2 can be controlled to predetermined levels. Further, a backside gas supply line 30 for supplying a cold heat transfer gas (backside gas) such as helium gas or the like to the backside of the semiconductor wafer W is formed to extend through the mounting table 2 and the like. With such configuration, the semiconductor wafer W attracted and held on the top surface of the mounting table 2 can be controlled to a predetermined temperature.

The shower head 16 is disposed at a ceiling portion of the processing chamber 1. The shower head 16 includes a main body 16a and an upper ceiling plate 16b serving as an electrode plate. The shower head 16 is held at an upper portion of the processing chamber 1 via an insulating member 45. The main body 16a is made of a conductive material, e.g., aluminum having an anodically oxidized surface, and the upper ceiling plate 16b can be detachably held under the main body 16a.

A gas diffusion space 16c is formed inside the main body 16a. A plurality of gas holes 16d is formed in the bottom portion of the main body 16a to be positioned under the gas diffusion space 16c. Further, gas inlet holes 16e are formed in the upper ceiling plate 16b to extend therethrough in its thickness direction and communicate with the gas holes 16d. With such configuration, a processing gas supplied to the gas diffusion space 16c is distributed and supplied in a shower shape into the processing chamber 1 through the gas holes 16d and the gas injection holes 16e. Moreover, a line (not shown) for circulating a coolant is provided in the main body 16a and the like so that the shower head 16 can be cooled to a desired temperature during a plasma etching process.

A gas inlet port 16g for introducing the processing gas into the gas diffusion space 16c is formed in the main body 16a. The gas inlet port 16g is connected to one end of a gas supply line 15a. The other end of the gas supply line 15a is connected to a processing gas supply source 15 for supplying a processing gas via a gas control unit 15b for controlling types or a mixing ratio of gases supplied to the gas inlet port 16g. The gas control unit 15b is also connected to a gas exhaust unit 15c for exhausting gas in the gas diffusion space 16c through the gas supply line 15a and an additional gas supply line 15g for directly supplying an additional gas to the processing space lb.

A variable DC power supply 52 is electrically connected to the shower head 16 serving as the upper electrode via a low pass filter (LPF) 51. The power supply of the variable DC power supply 52 can be turned on/off by an on/off switch 53. The current and voltage supplied from the variable DC power supply 52 and the on/off operation of the on/off switch 53 are controlled by a control unit 60 to be described later. As will be described later, when a plasma is generated in the processing space by applying the high frequency powers from the first and the second high frequency power supply 10a and 10b to the mounting table 2, the on/off switch 53 is turned on by the control unit 60 if necessary and, thus, a predetermined DC voltage is applied to the shower head 16 serving as the upper electrode.

A cylindrical ground conductor 1a extends from the sidewall of the processing chamber 1 to be positioned above the height of the shower head 16. The cylindrical ground conductor 1a has a ceiling plate at an upper portion thereof.

A gas exhaust port 71 is formed at a lower portion of the processing chamber 1, and a gas exhaust unit 73 is connected to the gas exhaust port 71. The gas exhaust unit 73 has a vacuum pump. By operating the vacuum pump, the processing chamber 1 can be depressurized to a predetermined vacuum level. Further, a loading/unloading port 74 for the wafer W is provided at a sidewall of the processing chamber 1, and a gate valve 75 for opening and closing the loading/unloading port 74 is provided at the loading/unloading port 74.

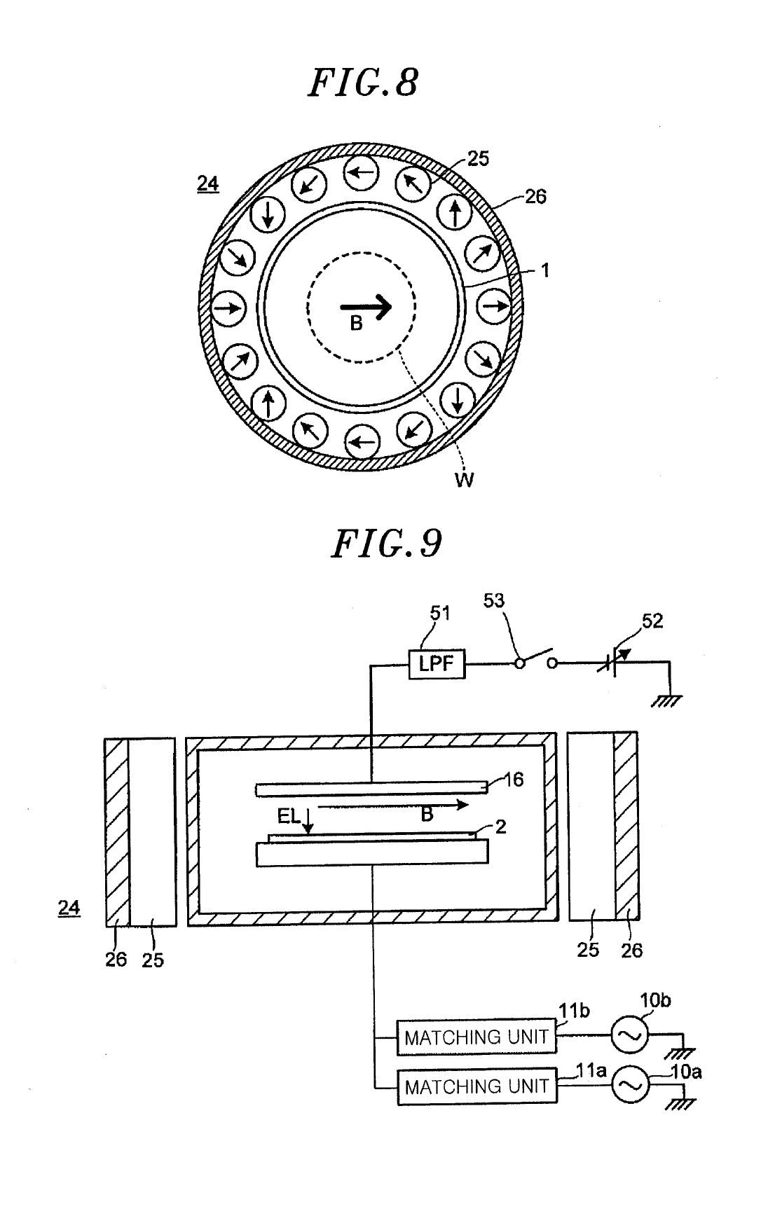

A dipole ring magnet 24 extending in a ring shape or a coaxial shape is provided around the processing chamber 1 at a position corresponding to the vertical position of the mounting table 2 during the processing. As shown in the horizontal cross sectional view of FIG. 8, the dipole ring magnet 24 is formed at a regular interval along the circumferential direction by arranging a plurality of, e.g., 16 anisotropic segment columnar magnets 25 in a casing 26 made of a ring-shaped magnetic material. In FIG. 8, arrows in the anisotropic segment columnar magnets 25 indicate magnetization directions. By slightly shifting the magnetization directions of the anisotropic segment columnar magnets 25 along the circumferential direction of the casing 26 as shown in FIG. 8, a uniform horizontal magnetic field B directed in one direction can be generated.

Therefore, in the space between the mounting table 2 and the shower head 16, a vertical RF electric field EL is generated by the first high frequency power supply 10a and a horizontal magnetic field B is generated by the dipole ring magnet 24 as schematically shown in FIG. 9. A high density plasma can be generated near the surface of the mounting table 2 by the magnetron discharge using orthogonal electromagnetic fields thereof.

The entire operation of the plasma etching apparatus configured as described above is controlled by the control unit 60. The control unit 60 includes: a process controller 61 having a CPU, for controlling the respective units of the plasma etching apparatus; a user interface 62; and a storage unit 63.

The user interface 62 has a keyboard for a process manager to input commands to manage the plasma etching apparatus, a display for visualizing and displaying an operation status of the plasma etching apparatus and the like.

The storage unit 63 stores therein recipes including control programs (software) for implementing various processes performed in the plasma etching apparatus under the control of the process controller 61, process condition data and the like. If necessary, a desired recipe is read out from the storage unit 63 in accordance with an instruction from the user interface 62 and executed in the process controller 61. Accordingly, a desired process is performed in the plasma etching apparatus under the control of the process controller 61. Further, the recipes such as the control programs, the process condition data and the like may be retrieved from a computer-readable storage medium (e.g., a hard disk, a CD, a flexible disk, a semiconductor memory or the like), or retrieved on-line through, e.g., a dedicated line from another apparatus whenever necessary.

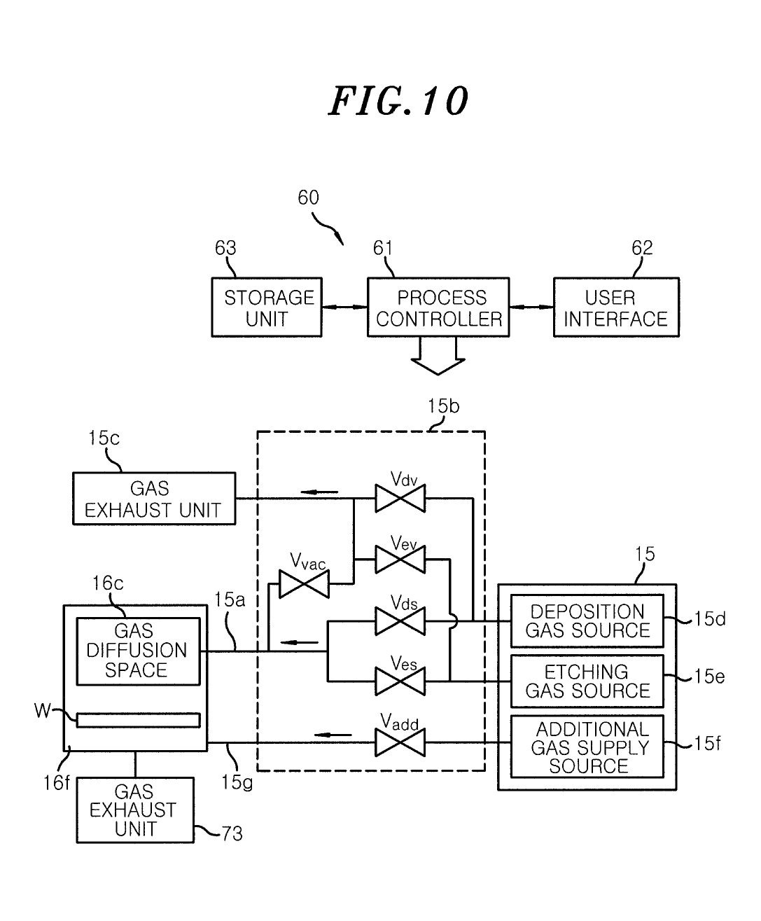

Hereinafter, the processing gas supply source 15 and the gas control unit 15b will be described in detail with reference to FIG. 10. As shown in FIG. 10, the processing gas supply source 15 includes a deposition gas source 15d for supplying a deposition gas used in the deposition step, an etching gas source 15e used in the etching step, and an additional gas supply source 15f for supplying an additional gas. The deposition gas source 15d supplies SiF₄, O₂ and the like as the deposition gas shown in FIG. 3. The etching gas source 15e supplies SF₆, HBr and the like as the etching gas shown in FIG. 3. The mixing ratio or the supply amount of the gases supplied from the deposition gas source 15d, the etching gas source 15e and the additional gas source 15f is determined by the control instruction from the controller 61. In other words, in the example shown in FIG. 3, the deposition gas source 15d and the etching gas source 15e supply SF₆, O₂, SiF₄, HBr and the like at respective flow rates in the plasma-etching-only process. In the same manner, the deposition gas source 15d supplies SiF₄, O₂ or the like at predetermined flow rates in the deposition step of the dynamic process, and the deposition gas source 15d and the etching gas source 15e supply SF₆, HBr, O₂ or the like at predetermined flow rates in the etching step.

The gas control unit 15b controls supply timing of the processing gas in the plasma-etching-only process or the dynamic process. The gas control unit 15b may control the supply flow rate or the mixing ratio of the processing gas. The gas control unit 15b includes a deposition supply valve V_{ds} connected to the supply line of the deposition gas source 15d, and an etching gas supply valve Vₛₑ connected to the supply line of the etching gas source 15e. The outputs of the deposition supply valve V_{ds} and the etching gas supply valve Vₑₛ are connected to the gas supply line 15a connected to the gas diffusion space 16c. Further, the gas control unit 15b includes a deposition exhaust valve V_{dv} connected to the supply line of the deposition gas supply source 15d, and an etching gas exhaust valve Vₑᵥ connected to the supply line of the etching gas source 15e. The outputs of the deposition exhaust valve V_{ds} and the etching gas exhaust valve Vₑᵥ are connected to the gas exhaust unit 15c. Moreover, the gas supply line 15a is connected to a diffusion space exhaust valve V_{vac} for exhausting the gas in the gas diffusion space 16c. The output of the diffusion space exhaust valve V_{vac} is connected to the gas exhaust unit 15c. The additional gas supply source 15f is connected to an additional gas valve V_{add}, and the output of the additional gas valve V_{add} is connected to the additional gas supply line 15g.

The opening and closing of the valves of the gas control unit 15b are controlled by the control instruction from the process controller 61. In other words, the process controller 61 controls the supply amount of the deposition gas and the etching gas to the gas diffusion space 16c by controlling the valves of the gas control unit 15b and realizes operation states of the plasma-etching-only process, and the deposition step and the etching step of the dynamic process by controlling the supply amount and the exhaust amount of the additional gas to the processing space 1b. The deposition gas or the etching gas whose flow rate or mixing ratio is controlled by the gas control unit 15b is supplied to the gas diffusion space 16c through the gas supply line 15a and then distributed in a shower shape from the gas diffusion space 16c to the processing space 1b of the processing chamber 1 through the gas holes 16d and the gas inlet holes 16e.

(Operation of the Plasma Etching Apparatus)

The outline of sequences of plasma processing for a semiconductor wafer W in the plasma etching apparatus configured as described above will be explained. First, the gate valve 75 is opened, and the semiconductor wafer W is loaded from a load lock chamber (not shown) into the processing chamber 1 by a transfer robot (not shown) through the loading/unloading port 74 and then mounted on the mounting table 2. Then, the transfer robot is retreated to the outside of the processing chamber 1, and the gate valve 75 is closed. Next, the processing chamber 1 is evacuated through the gas exhaust port 71 by the vacuum pump of the gas exhaust unit 73. The mounting table 2 is moved upward to a predetermined position for processing by the elevation unit (not shown).

After the processing chamber 1 is evacuated to a predetermined vacuum level, a processing gas (deposition gas and etching gas) is supplied from the processing gas supply source 15 into the processing chamber 1. When the pressure in the processing chamber 1 reaches a predetermined level, the pressure in the processing chamber 1 is maintained at that level. In that state, a high frequency power having a frequency of, e.g., 40 MHz, is supplied from the first high frequency power supply 10a to the mounting table 2. Further, a high frequency power for ion attraction (bias) having a frequency of, e.g., 2.0 MHz, is supplied from the second high frequency power supply 10b to the mounting table 2. At this time, a predetermined DC voltage is applied from the DC power supply 12 to the electrode 6a of the electrostatic chuck 6, so that the semiconductor wafer W is attracted and held on the electrostatic chuck 6 by a Coulomb force. The dipole ring magnet 24 generates a horizontal magnetic field B.

In that case, by supplying the high frequency power to the mounting table 2 serving as the lower electrode as described above, an electric field is formed between the shower head 16 serving as the upper electrode and the mounting table 2 serving as the lower electrode. Therefore, discharge occurs in the processing space 1b where the semiconductor wafer W is located. Accordingly, a plasma of the processing gas is generated, and the semiconductor wafer W is etched by the plasma. At this time, the on/off switch 53 is turned on if necessary to apply a predetermined DC voltage from the DC power supply 52 to the shower head 16 serving as the upper electrode.

The plasma etching method of the present embodiment includes a step of performing the plasma etching for a predetermined period of time by mixing the deposition gas and the etching gas and a step of repeating multiple times the deposition step in which the deposition gas is supplied and the etching step in which the etching gas is supplied at a relatively short cycle.

When all the processes are completed, the supply of the high frequency power, the supply of the DC voltage and the supply of the processing gas are stopped, and the semiconductor wafer W is unloaded from the processing chamber 1 in a reverse sequence to that described above.

Hereinafter, the plasma etching method of the present embodiment will be described in detail.

(Plasma Etching Method of the First Embodiment)

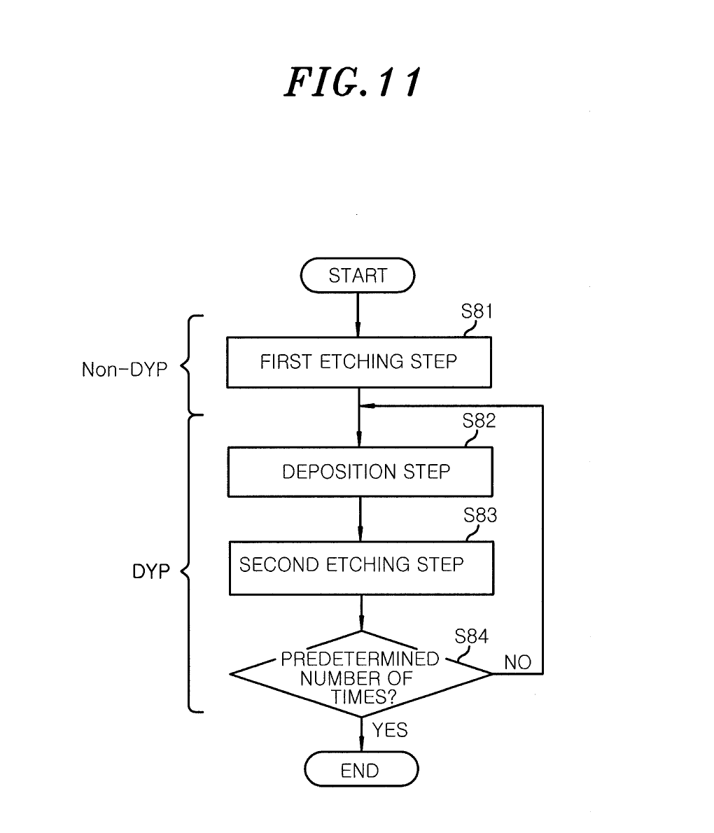

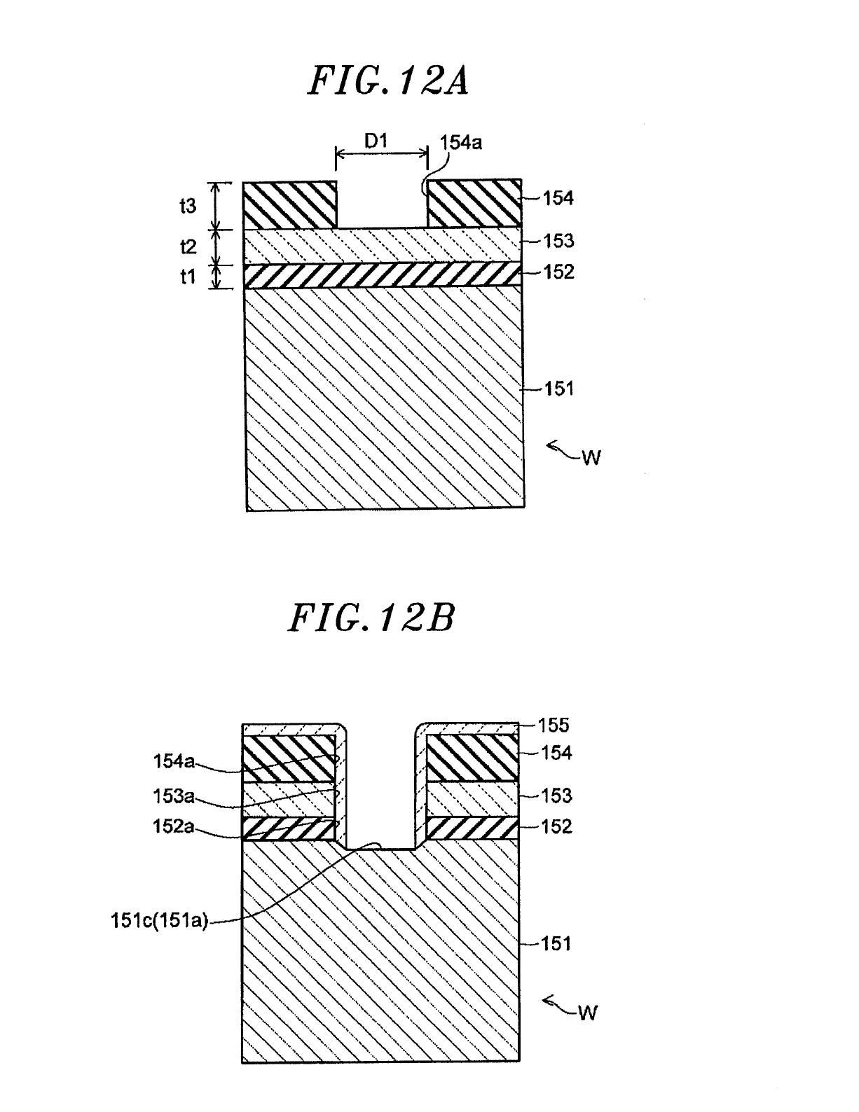

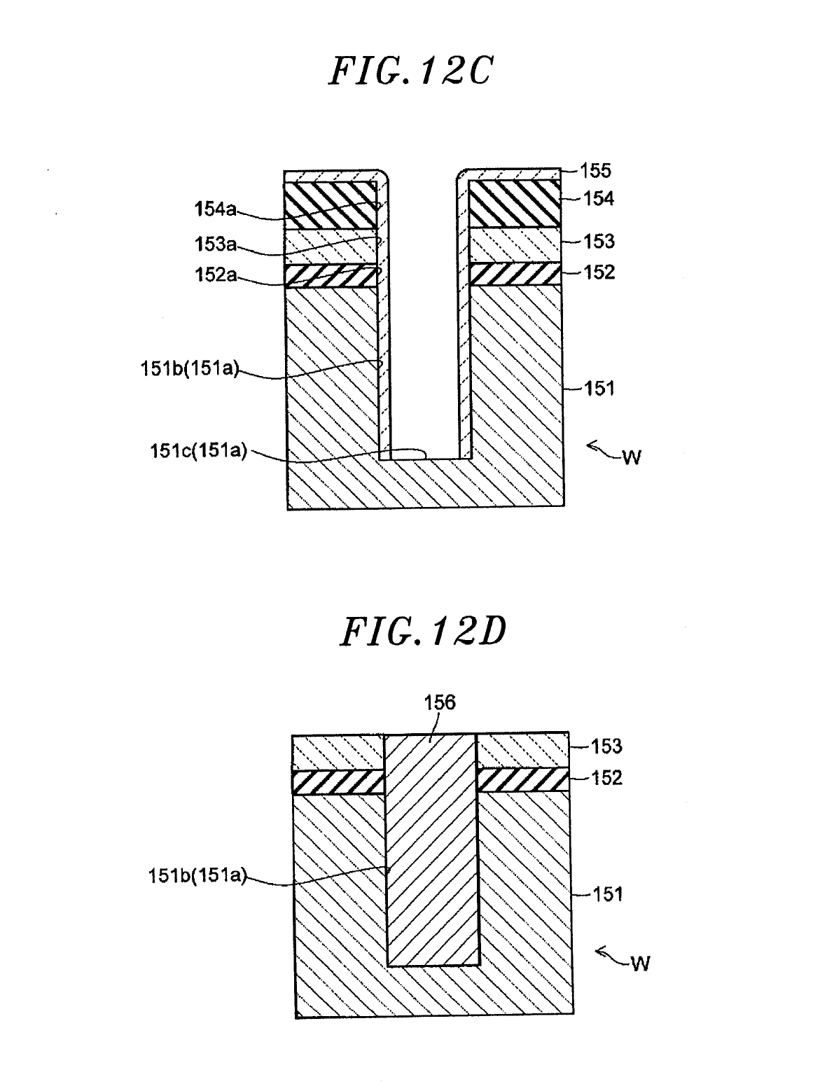

FIG. 11 is a flowchart describing the plasma etching method of the present embodiment. FIGS. 12A to 12D are cross sectional views schematically showing the state of the wafer in each step of the plasma etching method of the present embodiment. FIGS. 12A to 12D are enlarged views showing a region around one opening 154a on the wafer W. As shown in FIG. 11, the plasma etching method of the present embodiment includes the plasma-etching-only process (Non-DYP process) and the dynamic process (DYP process).

First, an example of a structure of a wafer W to which the plasma etching method is applied will be described. As shown in FIG. 12A, the wafer W has a structure in which a first hard mask film 152, a second hard mask film 153 and a mask film 154 are laminated on a base 151 made of, e.g., a single crystalline silicon (Si) layer in that order from the bottom. As for the first hard mask film 152, a silicon nitride (SiN) film having a thickness t1 may be used, for example. The thickness t1 may be, e.g., 0.5 μm. As for the second hard mask 153, a silicon oxide (SiOx) film having a thickness t2 may be used, for example. The thickness t2 may be, e.g., 0.5 μm. As for the mask film 154, a resist layer having a thickness t3 may be used, for example. The thickness t3 may be, e.g., 2.5 μm. Further, a circular opening 154a having an opening diameter (diameter) D1 of 8 μm is patterned at a plurality of positions on the mask film 154 by performing a photolithography process in advance.

Further, the first hard mask 152 may be a SiOx film, and the second hard mask film 153 may be a SiN film. The wafer W having the above structure is loaded into the processing chamber 1 and mounted on the mounting table 2.

The process controller 61 supplies SF₆, O₂, SiF₄ and HBr at the respective flow rates described in “Non-DYP” in FIG. 3 into the processing chamber 1 for a predetermined period of time by controlling the processing gas supply source 15 and the gas control unit 15b, thereby etching the silicon layer (step S81; hereinafter, it will be referred to as “S81”). The step S81 corresponds to the Non-DYP process. Specifically, in a state where the processing chamber 1 is exhausted by the gas exhaust unit 73, the processing gas (mixed gas) is introduced at a predetermined flow rate into the processing space 1b by the processing gas supply source 15 and the gas control unit 15b, and the pressure in the processing chamber 1 is set to a preset level. Further, in a state where the wafer W is fixed on the mounting table 2 by an electrostatic force generated by the DC power supply 12, the first high frequency power is supplied from the first high frequency power supply 10a to the mounting table 2. Accordingly, the etching gas injected from the shower head 16 is turned into a plasma by the magnetron discharge, and the plasma thus generated is irradiated to the wafer W.

By irradiating the plasma to the wafer W, openings 153a and 152a are respectively formed in the second and the first hard mask film 153 and 152 below the opening 154a of the mask film 154, and a hole 151a is formed on the base 151, as shown in FIG. 12B.

Although the mask layer 154 is etched by the plasma, the selectivity, i.e., the ratio of the etching rate of each of the second hard mask film 153, the first hard mask film 152 and the silicon layer 151 to the etching rate of the mask film 154 is considerably high. Thus, in FIG. 12B, changes in the film thickness of the mask film 54 are not illustrated (this is true in FIG. 12C). When fluorine radical F* generated by the conversion of the etching gas to the plasma reaches the hole 151a, SiF₄ is generated by the aforementioned reaction formula (1). Further, the silicon layer 151 is etched by discharging the generated SiF₄ to the outside of the hole 151a.

Meanwhile, when the etching gas is turned into a plasma, oxygen radical O* is generated. Silicon fluoride radical SiFx* is generated by reaction between SiF₄ generated by the reaction formula (1) and any plasma or reaction between fluorine radical F* and Si. For example, as indicated by the following reaction formula (2)

O*+SiFx*→SiOFx (2),

an SiO-based protective film 155 (e.g., SiOFx) is deposited on the sidewall of the hole 151a by reaction between oxygen radial O* and silicon fluoride radical SiFx*.

As shown in FIG. 12B, the protective film 155 is deposited on the top surface of the mask film 154, the sidewall of the opening 154a of the mask film 154, the sidewall of the opening 153a of the second hard mask film 153, the sidewall of the opening 152a of the first hard mask film 152, and the sidewall 151b of the opening 151a of the silicon layer 151 (see FIG. 12C). Since a bottom surface 151c of the hole 151a of the silicon layer 151 is farthest from the top surface of the wafer W, the deposition rate of the protective film at that portion is lower than that at the portion between the top surface of the mask film 154 and the sidewall 151b of the hole 151a of the silicon layer 151. Therefore, it is possible to perform anisotropic etching in which an etching rate of etching the hole 151a in a depth direction becomes faster than an etching rate of etching the hole 151a in a horizontal direction, and the sidewall 151b of the hole 151a can be formed to be perpendicular to the surface of the wafer W.

After a predetermined period of time elapses, the process controller 61 controls the processing gas supply source 15 and the gas control unit 15b to supply O₂ and SiF₄ at the respective flow rates in “deposition step” of “DYP” in FIG. 3 to the processing chamber 1 for a predetermined period of time, and the wafer W is subjected to the deposition (S82). The step S82 is included in the DYP process. Specifically, the gas control unit 15b evacuates the processing chamber 1 and introduces O₂ and SiF₄ into the processing space 1b at the respective flow rates in “deposition step” of “DYP” in FIG. 3, and the pressure in the processing chamber 1 is set to a preset level. At this time, the plasma emission state may be maintained by changing the processing gas while maintaining the pressure in the processing chamber 1 at a constant level. The deposition gas injected from the shower head 16 is turned into a plasma by the magnetron discharge, and the plasma is irradiated to the wafer W. At this time, the time for the deposition step is shorter than the processing time of the Non-DYP process (first etching step).

After the processing time of the deposition step elapses, the process controller 61 controls the processing gas supply source 15 and the gas control unit 15b to supply SF₆, O₂ and HBr at the respective flow rates in “etching step” of “DYP” in FIG. 3 for a predetermined period of time, and the silicon layer 151 of the wafer W is etched (S83). The step S83 is included in the DYP process. Specifically, the gas control unit 15b evacuates the processing chamber 1 and introduces SF₆, O₂ and HBr at the flow rates same as those in the etching step of FIG. 3 into the processing space 1b, and the pressure in the processing chamber 1 is set to a preset level. At this time, the processing gas is changed while maintaining the pressure in the processing chamber 1 at a constant level, so that the transition state of the plasma is maintained. The etching gas injected from the shower head 16 is turned into a plasma by the magnetron discharge, and the plasma is irradiated to the wafer W. At this time, the duration of the second etching step is shorter than the processing time of the Non-DYP process (first etching step).

After the processing time of the second etching step elapses, the process controller 61 determines whether or not the DYP process (the deposition step S82 and the second etching step S83) has been repeated for a predetermined number of times (S84). If the deposition step of the step S82 and the second etching step of the step S83 are not repeated the predetermined number of times (NO in S84), the process controller 61 repeats the steps S82 and S83 by controlling the processing gas supply source 15 and the gas control unit 15b (S82 and S83).

If the deposition step of the step S82 and the second etching step of the step S83 are repeated the predetermined number of times (YES in S84), the process controller 61 terminates the processing. FIG. 12C shows the cross section of the wafer W that has been subjected to the processing of the step S81 and multiple cycles of the processing of the steps S82 and S83. By performing the step S81 and multiple cycles of the steps S82 and S83, the etching of the silicon layer 151 is completed and the hole 151a is formed as shown in FIG. 12C.

Next, the mask film 154 is ashed by the plasma of the etching gas containing, e.g., O₂ gas, and the surface of the wafer W in which the mask film 154 is ashed is cleaned. Thereafter, a wiring metal 156, e.g., Cu or the like, is filled in the hole 151a by CVD (Chemical Vapor Deposition), electroplating, electroless plating or the like. Then, as shown in FIG. 12D, a residual wiring metal 156 formed on the surface of the wafer W is removed by CMP (Chemical Mechanical Polishing). When the second hard mask film 153 or the first hard mask film 152 is made of a silicon nitride film, an end point of the CMP processing may be detected at an upper end of the silicon nitride film by using the silicon nitride film as a stopper film of the CMP.

In a test example, the silicon wafer was plasma etched under the following conditions by using the plasma etching apparatus shown in FIG. 7.

Non-DYP process (first etching step S81):

(1) pressure: 200[mT], high frequency power (H/L): 2500 W/75 W, processing gas: SF₆/O₂/SiF₄/HBr=90/110/800/100[sccm], processing time:10 sec;

(2) pressure: 200[mT], high frequency power(H/L): 2500 W/0 W, processing gas: SF₆/O₂/SiF₄/HBr=140/140/900/150[sccm], processing time: 2 min;

(3) pressure: 200[mT], high frequency power(H/L): 2900 W/0 W, processing gas: SF₆/O₂/SiF₄/HBr=140/140/900/180[sccm], processing time: 2 min;

(4) pressure: 200[mT], high frequency power(H/L): 3000 W/0 W, processing gas: SF₆/O₂/SiF₄/HBr=140/140/900/180[sccm], processing time: 1 min.

DYP process (deposition step S82):

(5) pressure: 300[mT], high frequency power(H/L): 2000 W/200 W, processing gas: SF₆/O₂/SiF₄/HBr/SiCl₄=0/350/300/0/150[sccm], processing time: 6 sec;

DYP process (second etching step S83):

(6) pressure: 100[mT], high frequency power(H/L): 2000 W/200 W, processing gas: SF₆/O₂/SiF₄/HBr/SiCl₄=570/180/0/50/0[sccm], processing time: 10 sec;

Number of repetition of DYP process (S82 and S83): 52 times.

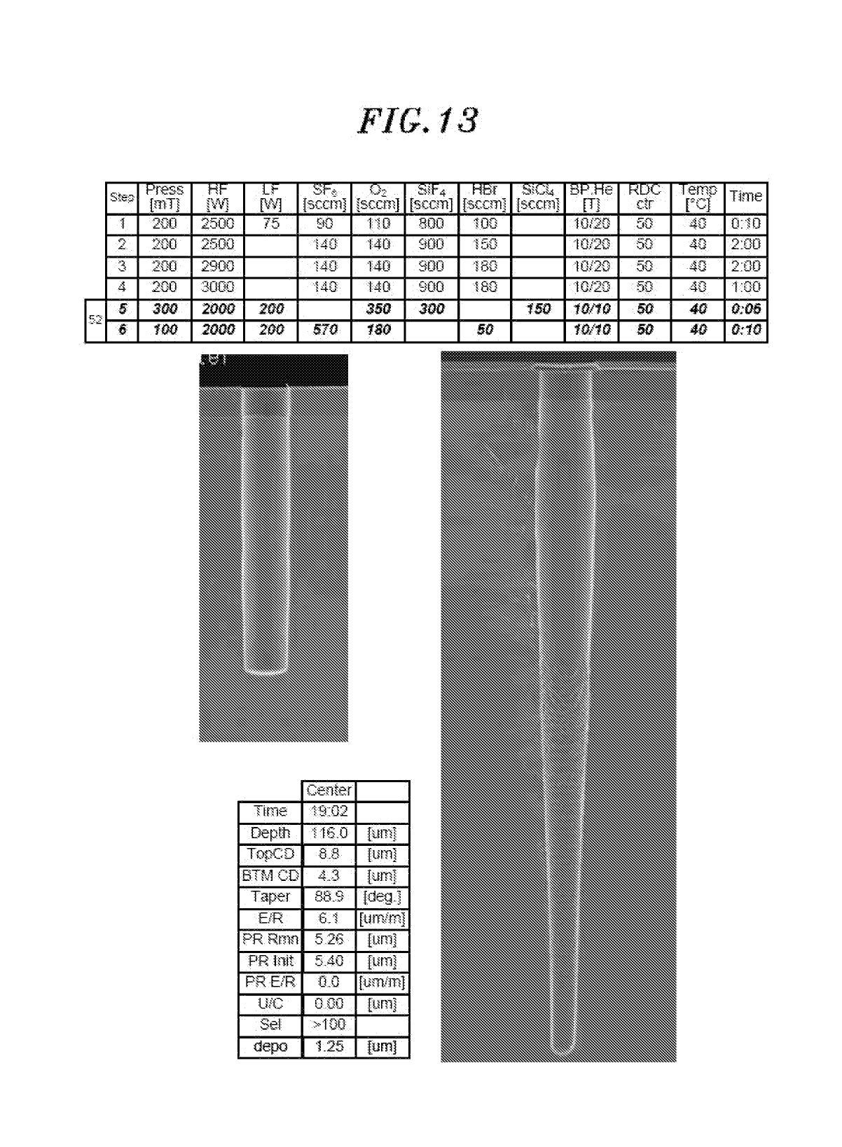

FIG. 13 shows the result of via formation in the test example 1. In two electron microscope images shown in FIG. 13, the left image shows a cross section obtained by forming a via by performing only the Non-DYP process, and the right image shows a cross section obtained by forming a via by performing the Non-DYP process and the DYP process. As shown in FIG. 13, a good via having a depth of 116.0 [μm] and a tapered angle of 88.9 was formed.

On the other hand, in a comparative example, the silicon wafer was plasma etched under the following conditions by using the plasma etching apparatus shown in FIG. 7.

Non-DYP process (first etching step S81):

(1) pressure: 200[mT], high frequency power(H/L): 2500 W/75 W, processing gas: SF₆/O₂/SiF₄/HBr=90/110/800/100[sccm], processing time: 10 sec;

(2) pressure: 200[mT], high frequency power(H/L): 2500 W/0 W, processing gas: SF₆/O₂/SiF₄/HBr=140/140/900/150[sccm], processing time: 2 min;

(3) pressure: 200[mT], high frequency power(H/L): 2900 W/0 W, processing gas SF₆/O₂/SiF₄/HBr=140/140/900/180[sccm], processing time: 2 min;

(4) pressure: 200[mT], high frequency power(H/L): 3000 W/0 W, processing gas: SF₆/O₂/SiF₄/HBr=140/140/900/180[sccm], processing time: 2 min. DYP process (deposition step S82)

(5) pressure: 300[mT], high frequency power(H/L): 2000 W/200 W, processing gas: SF₆/O₂/SiF₄/HBr/SiC1₄=0/350/300/0/150[sccm], processing time: 6 sec;

DYP process (second etching step S83)

(6) pressure: 100[mT], high frequency power(H/L): 2000 W/200 W, processing gas: SF₆/O₂/SiF₄/HBr/SiCl₄=570/180/0/50/0[sccm], processing time: 10 sec;

Number of repetition of DYP process (S82 and S83): 52 times.

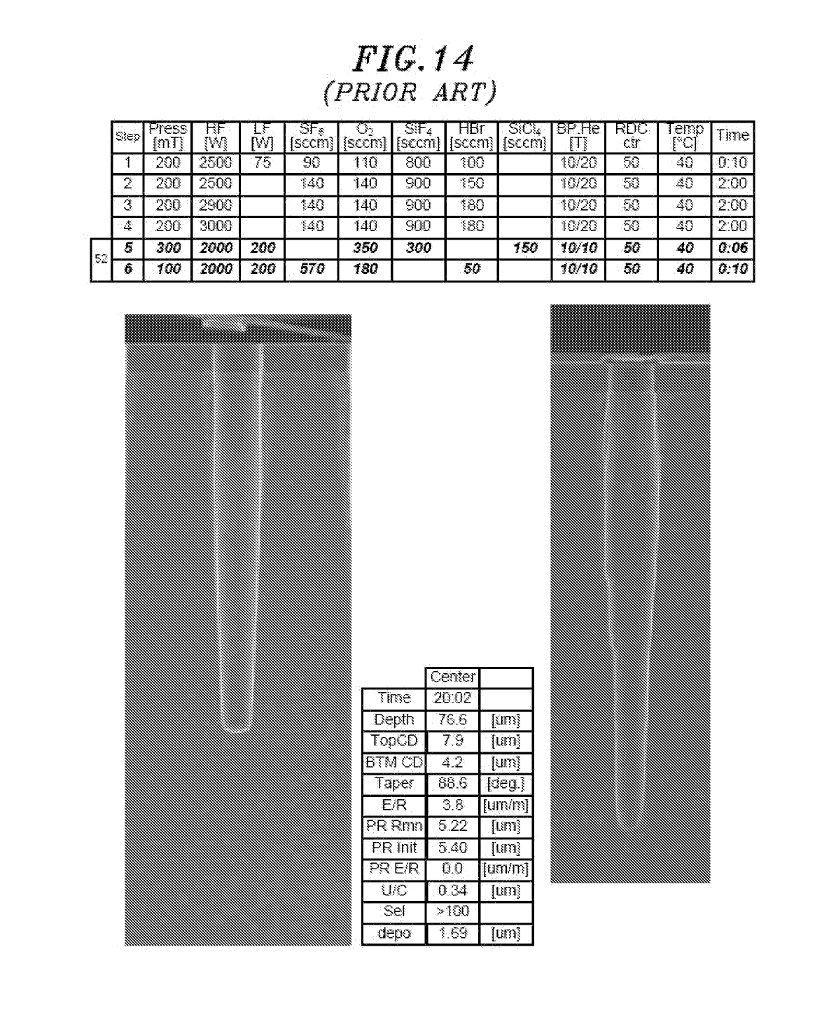

In other words, in the comparative example, the duration of the first etching step S81 is longer than that of the test example shown in FIG. 13. FIG. 14 shows the result of via formation in the comparative example. In two electron microscope images shown in FIG. 14, the left image shows a cross section obtained by forming a via by performing only the Non-DYP process, and the right image shows a cross section obtained by forming a via by performing the Non-DYP process and the DYP process. As shown in FIG. 14, in the comparative example, the final depth of the via is small and the wall surface of the via becomes rough, which results in the bowing. In the comparative example, the processing time of the Non-DYP process is long, so that the depth of the via formed by performing only the Non-DYP process is greater than that in the test example, and the diameter of the via bottom is smaller than that in the test example (test example: 7.7 [μm], comparative example: 5.1 [μm]). Therefore, it is considered that the etching gas did not sufficiently reach the via bottom in the etching step of the DYP process to make the depth of the via small. Further, it is considered that since the etching gas did not sufficiently reach the via bottom in the etching step of the DYP process, the deposition gas was not sufficiently introduced into the via in the deposition step of the DYP process to make the wall surface of the via rough.

The above results show that it is preferable to shift the Non-DYP process to the DYP process before the diameter of the via bottom becomes too small. In this example, it is preferable to shift the Non-DYP process to the DYP process before the diameter of the via bottom becomes 5.1 [μm] or less.

(Shifting timing of Non-DYP process and DYP process)

As shown in FIGS. 13 and 14, in the method of the present embodiment, if the diameter of the via bottom formed in the Non-DYP plasma-etching-only process is too small, the DYP process performed thereafter is not efficiently carried out. In other words, it is preferable to spread the deposition gas and the etching gas to the via bottom in the DYP process. Therefore, the shape of the via formed while varying the pressure in the processing chamber 1 and the output power of the first high frequency power supply 10a during the plasma etching was examined. FIG. 15 shows the shape of the via formed by the plasma etching (Non-DYP process) while varying the pressure in the processing chamber 1 and the plasma generation power condition of the first high frequency power supply 10a.

As shown in FIG. 15, as the plasma generation power of the first high frequency power supply 10a becomes low, the diameter is gradually reduced toward the via bottom and the shape of the via in the wafer W is not uniform. Meanwhile, if the plasma generation power is increased while maintaining the pressure in the processing chamber 1 at a constant level, the wall surface of the via becomes vertical and the sufficient diameter of the via bottom is ensured. Further, the shape of the via becomes uniform. In other words, if the pressure in the processing chamber 1 is kept unchanged, as the plasma generation power becomes higher, the shape of the via becomes uniform and the diameter of the via bottom is sufficiently ensured.

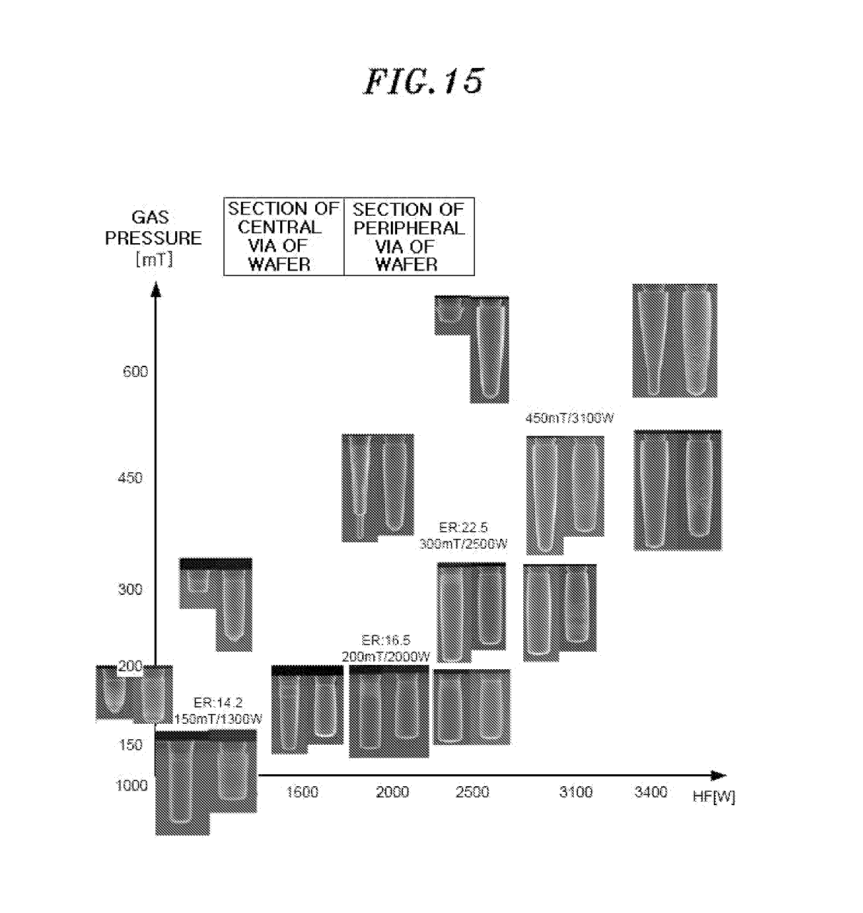

Meanwhile, in order to form a via having a high aspect ratio, it is important to maintain a high etching rate. Therefore, the via was formed while varying the pressure in the processing chamber 1 and the output power of the first high frequency power supply 10a in the plasma etching, and etching rates under the respective conditions were examined. FIG. 16 shows etching rates in the case of forming a via by performing the plasma etching (Non-DYP process) while varying the pressure in the processing chamber 1 and the plasma generation power condition of the first high frequency power supply 10a. As shown in FIG. 16, as the pressure in the processing chamber 1 is increased, the etching rate is increased. However, when the plasma generation power is increased while maintaining the pressure in the processing chamber 1 at a constant level, the etching rate starts to be decreased at a certain power level.

In other words, in view of ensuring a good etching rate and the sufficient diameter of the via, it is preferable to set a processing gas pressure in which an excellent etching rate is obtained while increasing the plasma generation power.

(Plasma Etching Method of Second Embodiment)

Hereinafter, a plasma etching method in accordance with another embodiment will be described. In the plasma etching method of the present embodiment, the same plasma etching apparatus as that of the first embodiment can be used. Therefore, like reference numerals will be used for like parts identical to those described in the first embodiment, and redundant description thereof will be omitted.

In the plasma etching method of the present embodiment, a through hole is formed in a wafer by using a TSV (Through-Silicon Via) technique in order to form a through electrode in a three-dimensional mounting semiconductor device. Thus, the plasma etching method of the present embodiment is different from that of the first embodiment in that a wafer obtained by adhering a wafer where the through hole is to be formed (hereinafter, referred to as “device wafer”) to a support wafer by an adhesive is etched.

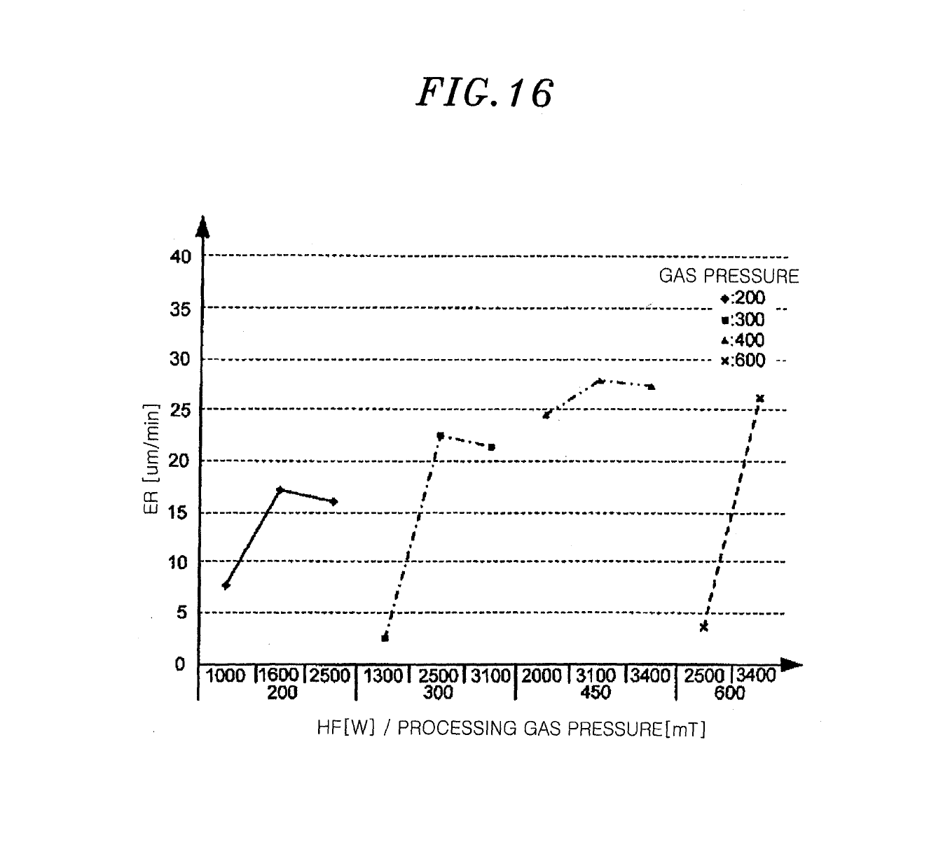

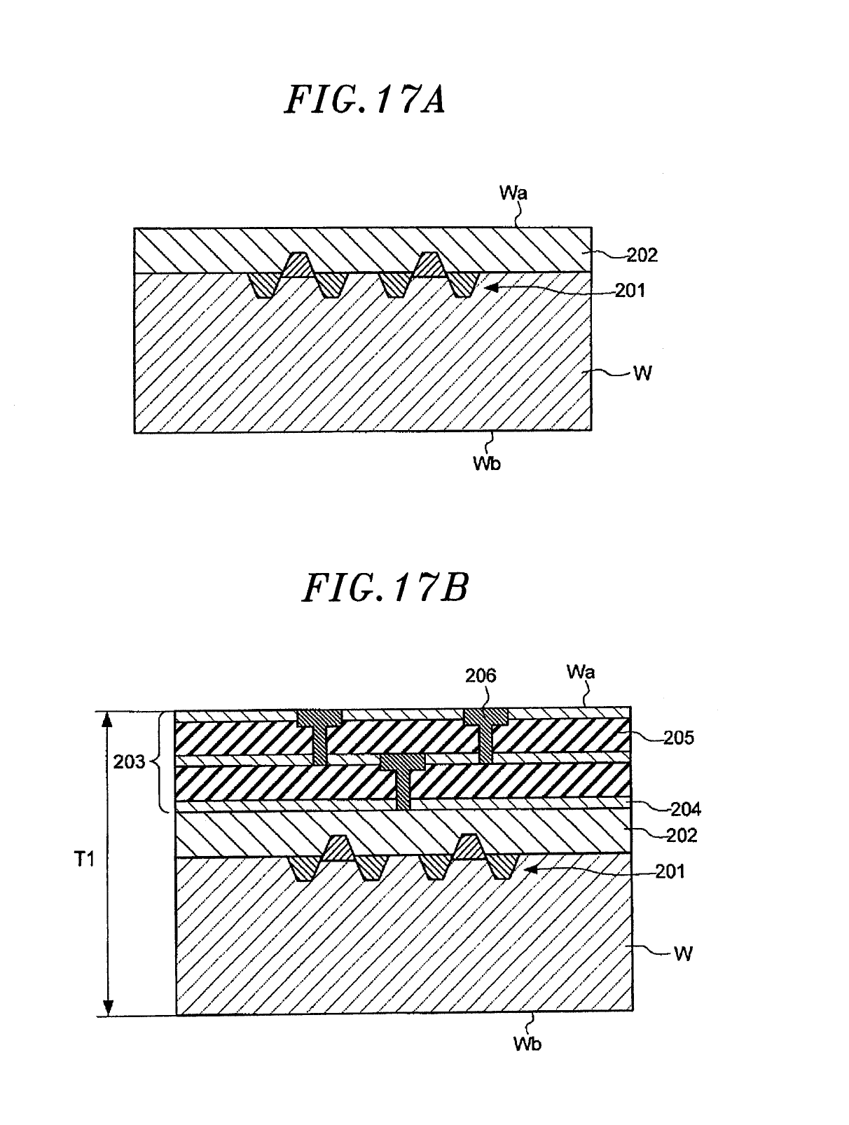

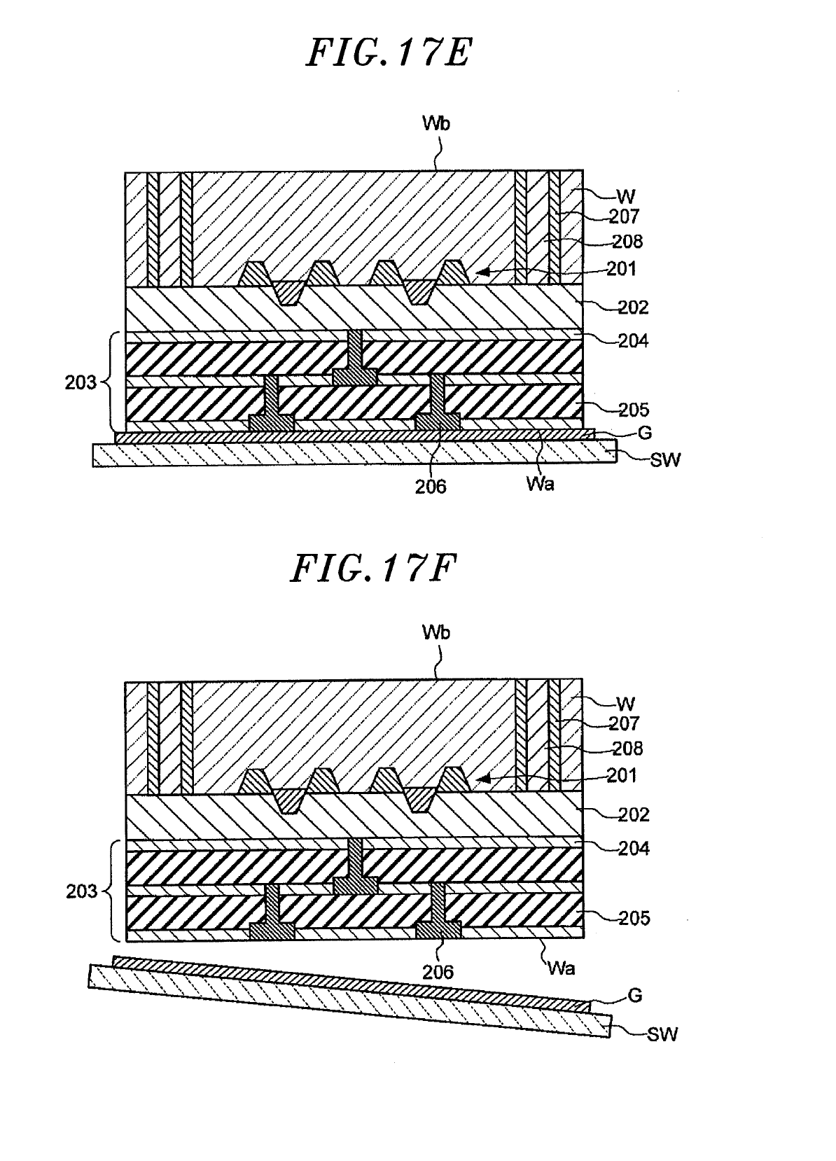

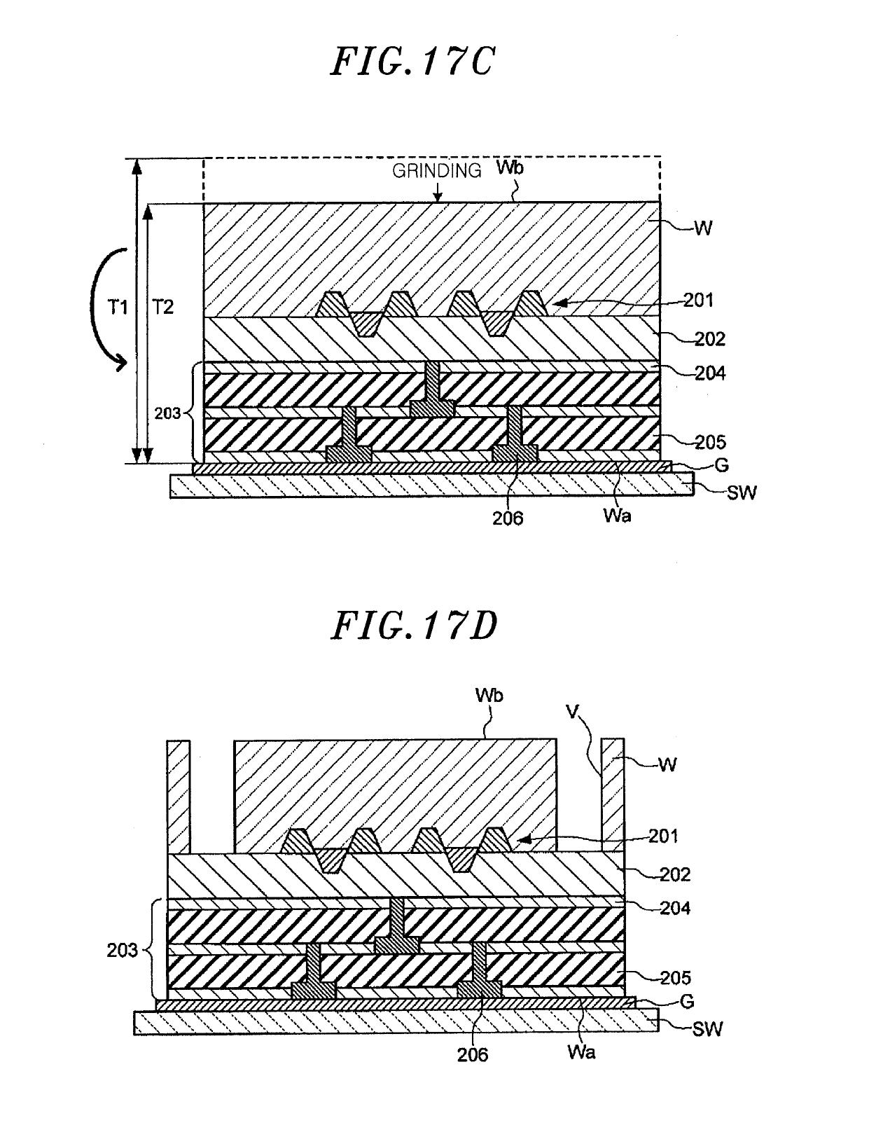

FIGS. 17A to 17F are cross sectional views schematically showing wafer states in the processes of the semiconductor device manufacturing method including the plasma etching method of the present embodiment.

As shown in FIG. 17C, a bonded wafer has a device wafer W and a support wafer SW. The device wafer W has on a surface Wa thereof semiconductor devices such as a transistor and the like. The support wafer SW supports the device wafer W that is thinned by grinding a backside Wb. The device wafer W is adhered to the support wafer SW by an adhesive G.

In the semiconductor device manufacturing method of the present embodiment, first, a transistor 201 is formed on a surface of the device wafer W, e.g., a silicon wafer or the like, and an interlayer insulating film 202 is formed on the device wafer W where the transistor 201 is formed (FIG. 17A).

Next, a wiring structure 203 is formed on the interlayer insulating film 202. A wiring layer 204 and an insulating film 205 are alternately laminated on the interlayer insulating film 202 and, also, a via hole 206 for electrically connecting the upper and the lower wiring layer 204 while penetrating through the insulating film 205 is formed (FIG. 17B).

Next, the device wafer W is turned upside down and the surface Wa of the device wafer W is bonded to the support wafer SW by the adhesive G, thereby preparing the bonded wafer. The support wafer SW serves as a support substrate that reinforces the device wafer W and prevents the device wafer W from warping when the device wafer W is thinned by grinding the backside Wb. The support wafer SW is, e.g., a silicon wafer or the like. Moreover, the bonded wafer is supported, e.g., at a support portion of a grinding device, and the backside Wb of the wafer W is grinded such that a thickness T1 of the device wafer W before grinding becomes a predetermined thickness T2 (FIG. 17C). The predetermined thickness T2 may be set to, e.g., 50 to 200 μm.

For simple illustration, the thicknesses of the interlayer insulating film 202 and the wiring structure 203 are exaggerated in FIGS. 17A to 17F. However, the actual thicknesses of the interlayer insulating film 202 and the wiring structure 203 are considerably smaller than the thickness of the base of the wafer W.

Next, a resist is coated on the backside Wb of the wafer W, exposed and developed. Accordingly, a resist pattern (not shown) is formed. Further, a through hole V is formed by etching the backside Wb of the wafer W by performing the same plasma etching process as that of the first embodiment. The resist remaining on the backside Wb of the wafer W where the through hole V is formed is removed by ashing as in the plasma etching method of the first embodiment (FIG. 17D). The diameter of the through hole V may be set to, e.g., 1 to 10 μm. Further, the depth of the through hole V corresponds to the thickness of the base of the wafer W that has been thinned by grinding the backside Wb of the wafer W and may be set to, e.g., 50 to 200 μm.

Next, an insulating film 207 made of, e.g., polyimide, is formed to cover the inner peripheral surface of the through hole V, and a through electrode 208 is formed by electroplating or the like in the through hole V having the inner peripheral surface coated with the insulating film 207 (FIG. 17E).

Next, the wafer W that has been thinned and has the through electrode 208 is obtained by peeling the support wafer SW from the wafer W. For example, the support wafer SW can be peeled by weakening the adhesive force of the photoreactive adhesive G by irradiating ultraviolet light (UV light) (FIG. 17F).

In the present embodiment as well, in the plasma etching step of FIG. 17D, the plasma etching in which the Non-DYP process and the DYP process are combined is carried out. Accordingly, a via having a high aspect ratio and a smooth wall surface can be formed.

While the invention has been shown and described with respect to the embodiments, it will be understood by those skilled in the art that various changes and modification may be made without departing from the scope of the invention as defined in the following claims.

### DESCRIPTION OF REFERENCE NUMERALS

1: processing chamber 2: mounting table
15: processing gas supply source
16: shower head
10a: first high frequency power supply
10b: second high frequency power supply
60: control unit
200: plasma etching apparatus
W: semiconductor wafer

What is claimed is:

1. A semiconductor device manufacturing method comprising:
a step of holding a substrate to be processed in a processing chamber, the substrate having a resist layer formed in a predetermined pattern on a main surface of a silicon layer;
a first etching step in which a mixed gas having a deposition gas and an etching gas mixed at a predetermined ratio is introduced into a processing chamber and the substrate is plasma etched in the mixed gas atmosphere by using the resist layer as a mask; and
a repetition step of repeating a plurality of times a deposition step in which the deposition gas is introduced into the processing chamber and the substrate that has been plasma etched in the first etching step is subjected to deposition treatment in an atmosphere having the deposition gas as a main component and a second etching step in which the etching gas is introduced into the processing chamber and the substrate that has been subjected to the deposition treatment in the deposition step is plasma etched in an atmosphere having the etching gas as a main component.

2. The semiconductor device manufacturing method of claim 1, wherein in the repetition step, the deposition step and the second etching step are consecutively repeated at least three times without extinguishing a plasma.

3. The semiconductor device manufacturing method of claim 1, wherein the mixed gas contains SF₆, O₂ and SiF₄.

4. The semiconductor device manufacturing method of claim 1, wherein the deposition gas contains O₂ and SiF₄.

5. The semiconductor device manufacturing method of claim 1, wherein the etching gas contains SF₆ and O₂.

6. The semiconductor device manufacturing method of claim 1, wherein the repetition step is continued for a period of time longer than a processing time of the first etching step.
